(19) United States
(12) Patent Application Publication
(10) Pub. No.: US 2023/0092042 A1
(43) Pub. Date: Mar. 23, 2023

(54) DIFFRACTIVE OPTICAL ELEMENT, PARTITIONED UNIFORM LIGHT PROJECTION SYSTEM, ELECTRONIC DEVICE AND DESIGN METHOD

(71) Applicant: HANGZHOU UPHOTON OPTOELECTRONICS TECHNOLOGY CO., LTD., Hangzhou (CN)

(72) Inventors: Muyun WANG, Hangzhou (CN); Yuming SONG, Hangzhou (CN); Peng CHEN, Hangzhou (CN); Xiaodong YIN, Hangzhou (CN)

(21) Appl. No.: 18/059,040

(22) Filed: Nov. 28, 2022

Related U.S. Application Data
(63) Continuation-in-part of application No. PCT/CN2021/093807, filed on May 14, 2021.

(30) Foreign Application Priority Data
May 27, 2020 (CN) 202010463166.2
May 27, 2020 (CN) 202020929985.7

(51) Int. Cl. G02B 27/42; G02B 5/18; G02B 27/10; G02B 27/00

(52) U.S. Cl. CPC G02B 27/4233; G02B 5/18; G02B 27/0087; G02B 27/1086; H01S 5/183

(57) ABSTRACT

A diffractive optical element (10) comprises a microstructure plane provided thereon with at least one microstructural pattern unit. The diffractive optical element (10) can receive a light beam emitted from a partitioned light source array (20) and project a light field on a target surface (OB), wherein the partitioned light source array (20) comprises a plurality of light source arrays (20-1, 20-2, ..., 20-n) spaced along a first direction, and the microstructural pattern unit is configured to be capable of diverging and light homogenization-modulating a light beam emitted from a light source in the plurality of light source arrays (20-1, 20-2, ..., 20-n) along the first direction such that light field regions projected by adjacent light source arrays (20-1, 20-2, ..., 20-n) on the target surface are adjoined or overlapped with each other in the first direction. In the embodiments of the invention, there are gaps between adjacent partitions. The light source partitions are lightened in turn. When each light source partition is lightened, only a region in the target light field corresponding to the partition is illuminated uniformly. Moreover, when all partitions are lightened together, the whole target light field is illuminated uniformly. There is no dark space caused by gaps between partitions, thereby realizing uniform illumination of partitions in the target light field.

### TECHNICAL FIELD

The invention generally relates to the technical field of optics, and, in particular, to a diffractive optical element, a partitioned uniform light projection system, an electronic device and a design method.

### BACKGROUND ART

At present, the existing TOF (Time-Of-Flight) scheme in mobile phone industry is Indirect Time-Of-Flight. With an indirect scheme such as a change in the phases of an emission light field and a receiving light field, the distance from a target object is calculated. As compared with the ranging of time of flight with a direct time stamp, indirect measurement has significant errors. For example, when a plurality of targets are measured, values will be converted into a mean value to calculate a distance. Moreover, the ambient noise of indirect measurement has a great influence. Ranging by the Time of Flight directly using a time stamp solves these problems. For the market demands, Sony designs a sensor for Direct Time-Of-Flight. In order to match with the operation of the sensor, uniform illumination of partitions in a light field shall be provided. In addition, in many specific applications, uniformly distributed light fields within a scope shall be provided.

A vertical cavity surface emitting laser (VCSEL) is a widely used laser. Light homogenizing plates of some diffractive optical elements (DOE) homogenize light in a light field emitted from the whole VCSEL chip. However, when there are partitions in the VCSEL chip, and there are gaps between partitions, phase distributions of a light homogenizing plate of a DOE are calculated and designed for the overall emitting light field, and this may cause that a light field of a portion corresponding to a gap between partitions in a target light field region and that in other regions are not uniform, thereby affecting the reconstruction of 3D information.

The contents in the Background Art part are only technologies known to the inventor, not representing the prior art in the field.

### SUMMARY OF THE INVENTION

In view of at least one of the problems in the prior art, the invention provides a diffractive optical element, comprising a microstructure plane, the microstructure plane provided thereon with at least one microstructural pattern unit, the diffractive optical element capable of receiving a light beam emitted from a partitioned light source array and projecting a light field on a target surface, wherein the partitioned light source array comprises a plurality of light source arrays spaced along a first direction, and the microstructural pattern unit is configured to be capable of diverging and light homogenization-modulating a light beam emitted from a light source in the plurality of light source arrays along the first direction such that light field regions projected by adjacent light source arrays on the target surface are adjoined or overlapped with each other in the first direction.

According to one aspect of the invention, the plurality of light source arrays have intervals along a second direction which is vertical to the first direction, wherein the microstructural pattern unit is configured to be capable of diverging and light homogenization-modulating a light beam emitted from a light source in the plurality of light source arrays along the second direction such that the light field regions projected by adjacent light source arrays on the target surface are adjoined or overlapped with each other in the second direction.

According to one aspect of the invention, the diffractive optical element has a focal power such that a light beam emitted by each light source array is diverged in a first direction and/or a second direction, and the microstructural pattern unit is configured to be capable of perform uniform modulation within a divergent scope.

According to one aspect of the invention, the diffractive optical element has different focal powers in a first direction and a second direction such that the aspect ratio of the partitioned light source array is matched with that of a light field region on the target surface in the first direction and the second direction.

According to one aspect of the invention, the microstructural pattern unit is configured to be capable of splitting, diverging, and light homogenization-modulating a light beam emitted from a light source in the plurality of light source arrays along the first direction; and/or the microstructural pattern unit is configured to be capable of splitting, diverging, and light homogenization-modulating a light beam emitted from a light source in the plurality of light source arrays along the second direction.

According to one aspect of the invention, the microstructural pattern unit is configured to allow a light field projected by each light source array after divergence and homogenization to at least reach a half of an interval between adjacent light source arrays.

The invention further provides a partitioned uniform light projection system, comprising:
a partitioned light source array, the partitioned light source array comprising a plurality of light source arrays which have intervals along a first direction;
the diffractive optical element as claimed in any of claims 1-4, provided downstream of a light path of the partitioned light source array and capable of receiving a light beam emitted from the plurality of light source arrays and projecting a light field on a target surface.

The invention further provides an electronic device, comprising the partitioned uniform light projection system as claimed above.

The invention further provides a design method of a diffractive optical element, comprising:
obtaining parameters of the partitioned light source array which comprises a plurality of light source arrays, the plurality of light source arrays having intervals along a first direction, the parameters comprising widths of the intervals along the first direction;
obtaining parameters of a target light field on a target surface, comprising a distance between the target light field and the partitioned light source array;
calculating parameters of the diffractive optical element such that the diffractive optical element can diverge and light homogenization-modulate a light beam emitted from a light source in the plurality of light source arrays along the first direction such that light field regions projected by adjacent light source arrays on the target surface are adjoined or overlapped with each other in the first direction.

According to one aspect of the invention, the plurality of light source arrays have intervals along a second direction which is vertical to the first direction, wherein steps of calculating parameters of the diffractive optical element comprise: calculating the parameters of the diffractive optical element such that the diffractive optical element can diverge and light homogenization-modulate a light beam emitted from a light source in the plurality of light source arrays such that the light field regions projected by adjacent light source arrays on the target surface are adjoined or overlapped with each other in the second direction.

According to one aspect of the invention, the steps of calculating parameters of the diffractive optical element comprise:
calculating a first phase distribution of the diffractive optical element, the first phase distribution capable of providing a focal power such that a light beam emitted by each light source array is diverged in a first direction and/or a second direction;
calculating a second phase distribution of the diffractive optical element, the second phase distribution capable of light homogenization-modulating a light beam emitted by each light source array in a divergent scope in a first direction and/or a second direction; and
superposing the first phase distribution and the second phase direction.

According to one aspect of the invention, the steps of calculating parameters of the diffractive optical element comprise: the steps of calculating parameters of the diffractive optical element comprise: calculating different focal powers of the diffractive optical element in the first direction and the second direction according to the aspect ratio of the partitioned light source array in the first direction and the second direction and the aspect ratio of the target light field in the first direction and the second direction such that the aspect ratio of the partitioned light source array is matched with that of the target light field in the first direction and the second direction.

According to one aspect of the invention, the step of calculating parameters of the diffractive optical element comprise: calculating parameters of the diffractive optical element such that the diffractive optical element splits, diverges, and light homogenization-modulates a light beam emitted from a light source in the plurality of light source arrays along the first direction, and/or the diffractive optical element splits, diverges, and light homogenization-modulates a light beam emitted from a light source in the plurality of light source arrays along the second direction.

According to one aspect of the invention, a light field projected by each light source array after divergence and homogenization can at least reach a half of an interval between adjacent light source arrays.

The invention further provides an optical modulation element which is designed with the foregoing design method.

In embodiments of the invention, a column of partitions can be adopted, and two columns of partitions can also be adopted for a light source array, which may provide different solutions, respectively. There are gaps between adjacent partitions. Light source partitions are lightened in turn. When each light source partition is lightened, only a region corresponding to the partition in the target light field is illuminated uniformly. Moreover, when all partitions are lightened together, the whole target light field is illuminated uniformly, and there is no dark space caused by gaps between partitions, thereby realizing uniform illumination of partitions in the target light field.

### BRIEF DESCRIPTION OF THE DRAWINGS

The drawings that constitute part of the specification are provided for further understanding the invention, and are used for explaining the invention along with the schematic embodiments of the invention and explanation thereof, but do not make any limitation of the same. In the drawings:

FIG. 1 illustrates a schematic diagram of a partitioned uniform light projection system in accordance with one embodiment of the invention;

FIG. 2 illustrates a frontal schematic diagram of the partitioned light source array in accordance with one embodiment of the invention;

FIG. 3 illustrates a partial enlarged drawing of the partitioned light source array in FIG. 2, and illustrates how the diffractive optical element modulates light emitted from each light source;

FIG. 4 illustrates distribution of light fields projected in accordance with one preferred embodiment of the invention;

FIG. 5 illustrates a frontal schematic diagram of the partitioned light source array in accordance with another embodiment of the invention, the plurality of light source arrays have intervals in the first direction and the second direction;

FIG. 6 illustrates a partial enlarged drawing of the partitioned light source array in FIG. 5, and illustrates a schematic diagram of modulation of the diffractive optical element;

FIG. 7 illustrates the manner for modulating light emitted from each light source by the diffractive optical element in accordance with another embodiment of the invention;

FIG. 8 illustrates the manner for modulating light emitted from each light source by the diffractive optical element in accordance with a further embodiment of the invention;

FIG. 9 illustrates a design method of a diffractive optical element in accordance with one embodiment of the invention.

### DETAILED DESCRIPTION OF THE EMBODIMENTS OF THE INVENTION

Certain exemplary embodiments will be described below only in a brief manner. Just as those skilled in the art will recognize, changes in various ways to the embodiments described herein can be carried out without departing from the spirit or scope of the invention. Therefore, the drawings and the following description are deemed essentially exemplary, instead of limitative.

In the description of the invention, it needs to be understood that the orientation or position relations denoted by such terms as “central” “longitudinal” “latitudinal” “length” “width” “thickness” “above” “below” “front” “rear” “left” “right” “vertical” “horizontal” “top” “bottom” “inside” “outside” “clockwise” “counterclockwise” and the like are based on the orientation or position as shown in the accompanying drawings, and are used only for the purpose of facilitating description of the invention and simplification of the description, instead of indicating or suggesting that the denoted devices or elements must be oriented specifically, or configured or operated in some specific orientation. Thus, such terms should not be construed to limit the invention. In addition, such terms as “first” and “second” are only used for the purpose of description, rather than indicating or suggesting relative importance or implicitly indicating the number of the designated technical features. Accordingly, features defined with “first” or “second” may, expressly or implicitly, include one or more of such features. In the description of the invention, “plurality” means two or above, unless otherwise defined explicitly and specifically.

In the description of the invention, it needs to be noted that, unless otherwise specified and defined explicitly, such terms as “mount” “link” and “connect” should be understood as generic terms. For example, connection may refer to fixed connection, dismountable connection, or integrated connection; also to mechanical connection, electrical connection or intercommunication; further to direct connection, or indirect connection by an intermediary medium; or even to internal communication between two elements or interaction between two elements. For those skilled in the art, they can construe the specific meaning of such terms herein in light of the specific circumstances.

Herein, unless otherwise specified and defined explicitly, if a first feature is “above” or “below” a second one, this may cover the direct contact between the first and second features, also cover the contact via another feature therebetween, instead of the direct contact. Furthermore, if a first feature “above”, “over” or “on the top of” a second one, this may cover the case that the first feature is right above or on the inclined top of the second feature, or just indicate that the first feature has a horizontal height higher than that of the second feature. If a first feature is “below”, “under” or “on the bottom of” a second feature, this may cover the case that the first feature is right below and on the inclined bottom of the second feature, or just indicates that the first feature has a horizontal height lower than that of the second feature.

The disclosure below provides many different implementations or cases so as to realize different structures described in the invention. In order to simplify the disclosure of the invention, the parts and arrangements embodied in specific cases will be described below. Surely, they are just for the exemplary purpose, not intended to limit the invention. Besides, the invention may repeat a reference number and/or reference letter in different cases, and such repeat is for the purpose of simplification and clarity, which does not represent any relationship among various implementations and/or arrangements as discussed. In addition, the invention provides cases of various specific techniques and materials, but those skilled in the art can also be aware of application of other techniques and/or use of other materials.

The embodiments of the invention will be introduced below with reference to the drawings. It should be appreciated that the embodiments described here are only for the purpose of illustrating and explaining, instead of restricting, the invention.

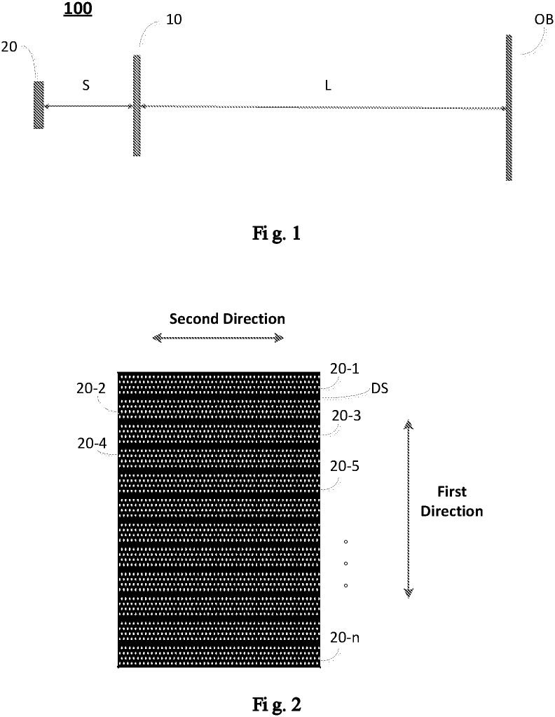

FIG. 1 illustrates a schematic diagram of a partitioned uniform light projection system 100 in accordance with one embodiment of the invention. The partitioned uniform light projection system 100 comprises a diffractive optical element 10 and a partitioned light source array 20, wherein the partitioned light source array 20 comprises a plurality of light source arrays (see FIG. 2), and the plurality of light source arrays have intervals along a first direction, which will be described herein in detail. The diffractive optical element 10 is provided downstream of a light path of the partitioned light source array 20, and can receive a light beam emitted from the plurality of light source arrays and project a uniform light field on a target surface OB.

FIG. 2 illustrates a frontal schematic diagram of a partitioned light source array 20. As shown in FIG. 2, the partitioned light source array 20 comprises a plurality of light source arrays 20-1, 20-2, ..., and 20-n, wherein for example, due to limitation of process, there are intervals between adjacent light source arrays. As shown in FIG. 2, there is a certain interval DS between light source arrays in a first direction (the vertical direction in the Figure). The light source array, for example, comprises a plurality of vertical cavity surface emitting lasers.

Within each light source array, there are small intervals between adjacent light sources (or light emitting points). Thus, after modulated by the diffractive optical element 10, light beams emitted from each light source can be overlapped with each other, thereby projecting a uniform light field. There is generally a big interval DS between adjacent light source arrays, greater than a distance between adjacent light sources (or light emitting points) in the same light source array. If the diffractive optical element 10 does not perform special optical modulation, there will be many dark shadow regions along a second direction in the light field projected on the target surface OB.

The diffractive optical element 10 has a microstructure plane which is provided thereon with at least one microstructural pattern unit of various phase distribution. According to the invention, the microstructural pattern unit is configured to be capable of diverging and light homogenization-modulating a light beam emitted from a light source in the plurality of light source arrays along the first direction such that light field regions projected by adjacent light source arrays on the target surface OB are adjoined or overlapped with each other in the first direction. Thus, through the diffractive optical element 10, a uniform light field can be projected out on the target surface OB by a light beam emitted from the partitioned light source array 20, and dark shadow regions that may be brought about by intervals between adjacent light source arrays can be eliminated.

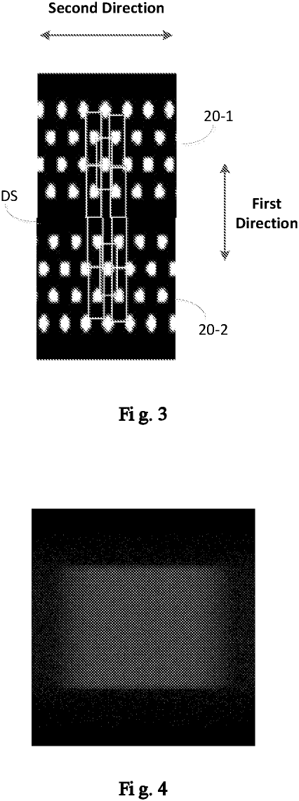

FIG. 3 illustrates a partial enlarged drawing of the partitioned light source array 20, and illustrates how the diffractive optical element 10 modulates light emitted from each light source. As shown in FIG. 3, light source arrays 20-1 and 20-2 are shown, and they have an interval DS along a first direction. The diffractive optical element 10 receives light beams from light source arrays 20-1 and 20-2, and diverge and light homogenization-modulate the light beams along the first direction such that after modulation, a portion in the emergent light field corresponding to the interval DS is covered by a uniform light field. As shown in FIG. 3, a light beam from each light source is diverged and broadened by the diffractive optical element 10 along the first direction (as illustrated by many rectangular frames in FIG. 3), and is light homogenization-modulated within a divergent scope. The extent to which the diffractive optical element 10 diverges and broadens light beams can be determined according to an operating distance L between the diffractive optical element 10 and a target surface. For example, when projected onto the target surface, light fields corresponding to two adjacent light source arrays can be at least adjoined as shown in FIG. 3 so as to eliminate a dark shadow region that may be formed by an interval DS between adjacent light source arrays in the target light field. FIG. 4 illustrates distribution of light fields projected in accordance with one preferred embodiment of the invention.

The diffractive optical element 10 in the embodiment of FIG. 1 can be realized by a single piece of DOE. A schematic diagram of the partitioned uniform light projection system 100 is as shown in FIG. 1. The operating distance L between the diffractive optical element 10 and the target surface is 1,500 mm for example. As the distance S between the diffractive optical element 10 and the partitioned light source array 20 is quite short, i.e. only several millimeters, the target light field can be approximately considered as imaging at infinity. In addition, as shown in FIG. 2, the partitioned light source array 20 has one column, and there is no gap between partitions in horizontal direction. Thus, the diffractive optical element 10 achieves the function of light homogenizing, and is equivalent to a light homogenizing plate. Light is homogenized for each light emitting point of the VCSEL (20 degrees of FOV) to match with the FOV angle of a target light field, for example, 50-80 degrees. In a vertical direction, due to a gap between partitions, the diffractive optical element 10 has a focal power. The divergence angle of a light beam emitted from a light emitting point is limited in a vertical direction, which is equivalent to the function of a cylindrical mirror. Moreover, light is homogenized in the region within a limited divergence angle such that the light emitted from light emitting points on the edges of two adjacent partitions is adjoined or overlapped with each other in a target field so as to cover a target light field region corresponding to a gap between partitions. It can be understood as follows: the diffractive optical element 10 has the three functions above, namely, light homogenizing along a second direction; divergence along a first direction; and light homogenizing along a first direction. With regard to the three functions above, different phase distributions of the diffractive optical element 10 that realize corresponding functions can be calculated, respectively, and then the phase distributions calculated are superposed so as to design the overall phase distribution of the diffractive optical element 10 device as desired.

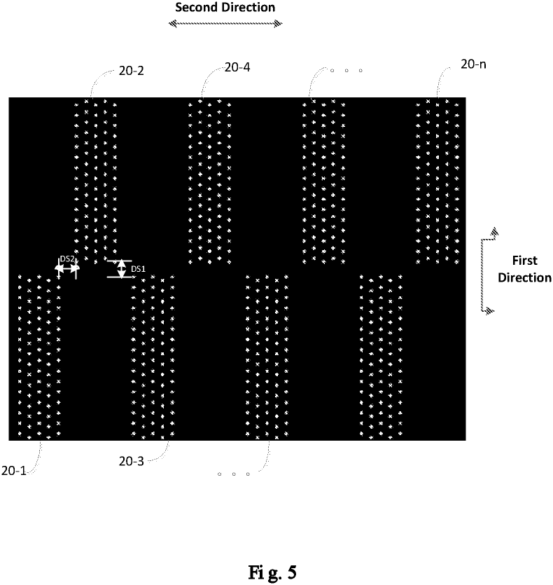

In embodiments of FIG. 2 - FIG. 4, a plurality of light source arrays have intervals along a first direction. The diffractive optical element 10 receives a light beam from a light source array, and diverges and light homogenization-modulates the light beam along the first direction so as to eliminate the intervals along the first direction. The invention is not limited thereto. FIG. 5 illustrates an embodiment where a plurality of light source arrays have intervals along a first direction and a second direction. As shown in FIG. 5, the partitioned light source array 20 comprises a plurality of light source arrays 20-1, 20-2, ..., and 20-n, wherein adjacent light source arrays have a first interval DS1 along a first direction, and have a second interval DS2 along a second direction, wherein the first direction is vertical to the second direction.

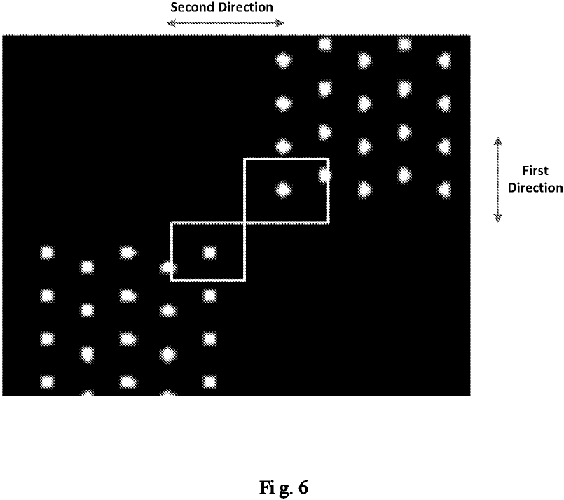

FIG. 6 illustrates a schematic diagram of modulation of the diffractive optical element 10 corresponding to FIG. 5. As shown in FIG. 6, the microstructural pattern unit of the diffractive optical element 10 is configured to be capable of diverging and light homogenization-modulating a light beam emitted from a light source in the plurality of light source arrays along the first direction and the second direction such that the light field regions projected by adjacent light source arrays on the target surface are adjoined or overlapped with each other in the first direction and the second direction. The rectangle in FIG. 6 identifies the manner for modulating a light beam emitted from each light source by the diffractive optical element 10. Specifically, the diffractive optical element 10 diverges and light homogenization-modulates the light beam along the first direction such that the light field regions projected by adjacent light source arrays on the target surface OB are at least adjoined with each other in the first direction to eliminate a dark shadow region. In addition, the diffractive optical element 10 diverges and light homogenization-modulates a light beam along the second direction such that the light field regions projected by adjacent light source arrays on the target surface are at least adjoined with each other in the second direction to eliminate a dark shadow region.

For realizing divergence of a light beam from each light source array in a first direction and/or a second direction, the diffractive optical element 10 can have a focal power in the first direction and/or the second direction, and the plurality of microstructural pattern units are configured to be capable of light homogenization-modulation within a divergent scope so as to ensure that the brightness of the light field projected is uniform as far as possible.

In addition, when the aspect ratio of a partitioned light source is different from that of a target light field, the diffractive optical element has different focal powers in the first direction and the second direction. That is, the divergence degree in the first direction is different from that in the second direction such that the aspect ratio of the partitioned light source array is matched with that of the light field region on the target surface in the first direction and the second direction.

With regard to the partitioned light source array illustrated in FIG. 5, the diffractive optical element 10 can also preferably be realized by a single piece of DOE. As there are gaps between partitions in the partitioned light source array in both horizontal and vertical directions, DOE shall have focal powers in two directions. A divergence angle of the light beam emitted from a light emitting point is defined in both horizontal and vertical directions, which is equivalent to the function of a lens. Moreover, light is homogenized in the region within a defined divergence angle such that the light emitted from light emitting points on the edges of two adjacent partitions is adjoined or overlapped with each other in the target field so as to cover a target light field region corresponding to a gap between partitions. When the diffractive optical element is designed, phase distributions (for example, the Fresnel lens provides a focal power, and a random phase structure is used for homogenizing light) of the DOE that realizes corresponding functions are calculated, respectively, and then the phase distributions calculated are superposed so as to design the overall phase distribution of the DOE device as desired. In addition, when the aspect ratio of the light emitting region of the VCSEL is different from that of the target light field in both horizontal and vertical directions, the DOE can provide different focal powers (a saddle-shaped phase distribution) in two directions to correct the aspect ratio of the light emitting region of the VCSEL so as to match with that of the target light field.

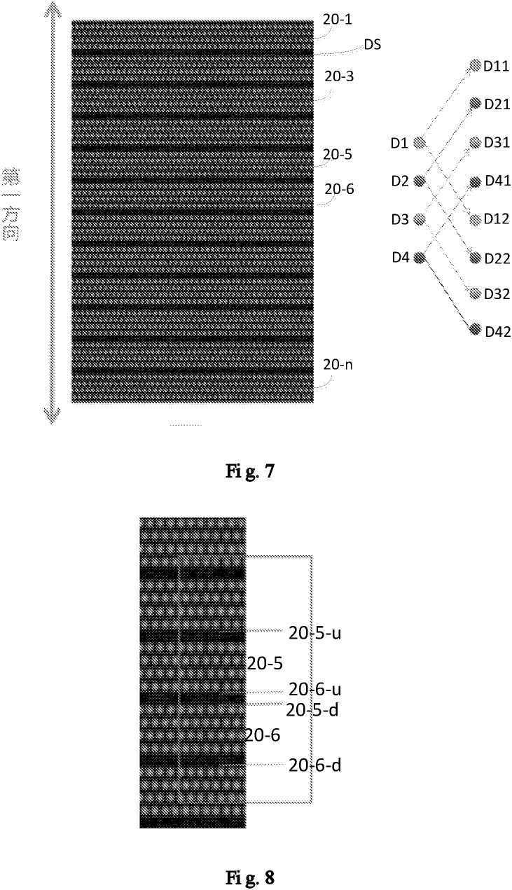

In the embodiments of FIG. 3 - FIG. 6 above, the microstructural pattern unit on the diffractive optical element 10 diverges and light homogenization-modulates a light beam emitted from a light source in the light source array along the first direction. According to another embodiment of the invention, the diffractive optical element 10 is configured to first split a light beam emitted from a light source, and then diverge and light homogenization-modulate light beams along the first direction following beam splitting. FIG. 7 illustrates such an embodiment. A detailed description is made by referring to FIG. 7.

As shown in FIG. 7, the partitioned light source array 20 comprises a plurality of light source arrays 20-1, 20-2, ..., and 20-n, wherein each light source array, for example, comprises four lines of light emitting points of the vcsel, there are intervals DS between adjacent light source arrays, and there are small distances between light emitting points in each light source array. A light splitting manner in accordance with one embodiment of the invention is illustrated on the right of FIG. 7. As shown in FIG. 7, each light source array comprises four lines of light emitting points. Taking any light source array as an example, D1, D2, D3, and D4 in the Figure each represent a light beam from a light emitting point in the first line, the second line, the third line, and the fourth line respectively. According to the embodiment, the microstructural pattern unit on the diffractive optical element 10 splits each light beam into two beams first. For example, light beam D1 from the first line of light emitting points is split into D11 and D12; light beam D2 from the second line of light emitting points is split into D21 and D22; light beam D3 from the third line of light emitting points is split into D31 and D32; light beam D4 from the fourth line of light emitting points is split into D41 and D42. After beam splitting, as for light beams D11, D12, D21, D22, D31, D32, D41, and D42, each light beam is diverged and light homogenization-modulated along the first direction by the foregoing method described in FIG. 3 - FIG. 6, thereby obtaining a uniform light field after respective lightening in the whole FOV shown in FIG. 4. In addition, a light beam emitted from each light emitting point can also be split into three or more light beams. These fall within the scope of protection of the invention.

In addition, those skilled in the art will readily understand that the beam splitting solution described in FIG. 7 is similarly applicable to the embodiment in FIG. 6. That is, the microstructural pattern unit of the diffractive optical element 10 is configured to be capable of splitting, diverging, and light homogenization-modulating a light beam emitted from a light source in the plurality of light source arrays along the first direction and the second direction. This will not be repeated here.

Therefore, in the embodiment above, the diffractive optical element 10 has five functions, namely, light homogenizing along a second direction; divergence along a second direction; light splitting along a first direction; divergence along a first direction; light homogenizing along a first direction. With regard to the five functions above, as the diffractive optical element has a high design freedom, the five functions above can be integrated. That is, after all parameters are determined, use of only a single diffractive optical element can realize the several functions above.

According to another preferred embodiment of the invention, as for each light source array, preferably, a light field projected by each light source array after divergence and light homogenization can at least reach middle of an interval DS such that light field projected by adjacent light source arrays after divergence and light homogenization can be overlapped. Further preferably, a light field projected by each light source array after divergence and light homogenization can reach an edge of a light field projected by an adjacent light source arrays (not diverged and homogenized) such that there will be no region which is not lightened even in case of an assembly error. As shown in FIG. 8, light source arrays 20-5 and 20-6 are schematically illustrated, wherein, after a light beam emitted from the light source array 20-5 is diverged, homogenized, and optionally split, the scope of the light field in the first direction is defined by the upper boundary 20-5-u and the lower boundary 20-5-d. After a light beam emitted from the light source array 20-6 is diverged, homogenized, and optionally split, the scope of the light field in the first direction is defined by the upper boundary 20-6-u and the lower boundary 20-6-d. As shown in FIG. 8, the lower boundary 20-5-d of the light field of the light source array 20-5 is beyond a half of the interval DS between the light source array 20-5 and the light source array 206, and is close to the light source array 206; the upper boundary 20-6-u of the light source of the light source array 20-6 is beyond a half of the interval DS between the light source array 20-5 and the light source array 206, and is close to the light source array 20-5. Therefore, the light fields projected by the light source arrays 20-5 and 20-6 are overlapped with each other to some extent, ensuring that there will be no region which is not lightened even in case of an assembly error.

The forgoing describes a partitioned uniform light projection system and a diffractive optical element in accordance with embodiments of the invention. The forgoing partitioned uniform light projection system can be incorporated with an electronic device where uniform light projection is required, including but not limited to mobile phones, PADs, electronic locks and the like.

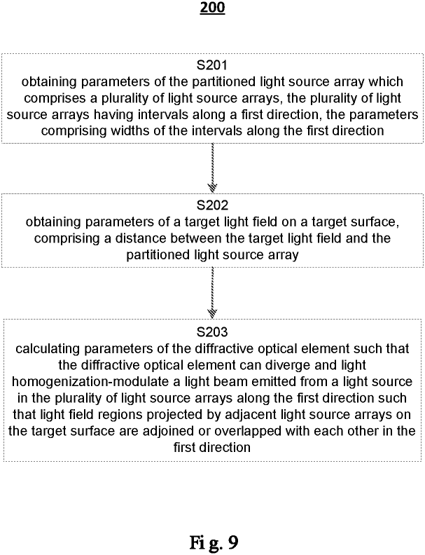

FIG. 9 illustrates a design method 200 of a diffractive optical element in accordance with one embodiment of the invention. Reference is made to the detailed description of FIG. 9 below. As shown in FIG. 9, the design method 200 comprises:

In step S201, parameters of a partitioned light source array are obtained. The partitioned light source array comprises a plurality of light source arrays. The plurality of light source arrays such as the partitioned light source array 20 as shown in FIG. 2 have an interval along a first direction. The parameters comprise the width of the interval DS along the first direction.

In step S202, parameters of a target light field on the target surface are obtained, comprising a distance between the target light field and the partitioned light source array.

In step S203, parameters of the diffractive optical element are calculated such that the diffractive optical element can diverge and light homogenization-modulate a light beam emitted from a light source in the plurality of light source arrays along the first direction such that light field regions projected by adjacent light source arrays on the target surface are adjoined or overlapped with each other in the first direction.

According to one embodiment of the invention, the plurality of light source arrays such as the partitioned light source array as shown in FIG. 5 have intervals along a second direction which is vertical to the first direction, wherein the step S203 comprises: parameters of the diffractive optical element are calculated such that the diffractive optical element can diverge and light homogenization-modulate a light beam emitted from a light source in the plurality of light source arrays such that the light field regions projected by adjacent light source arrays on the target surface are adjoined or overlapped with each other in the second direction.

According to one embodiment of the invention, the step S203 comprises:

A first phase distribution of the diffractive optical element is calculated, and the first phase distribution can provide a focal power such that a light beam emitted by each light source array is diverged in a first direction and/or a second direction.

A second phase distribution of the diffractive optical element is calculated, and the second phase distribution can light homogenization-modulate a light beam emitted by each light source array within a divergent scope in the first direction and/or the second direction; and

The first phase distribution and the second phase distribution are superposed.

According to one embodiment of the invention, the step S203 comprises: different focal powers of the diffractive optical element in the first direction and the second direction are calculated according to the aspect ratio of the partitioned light source array in the first direction and the second direction and the aspect ratio of the target light field in the first direction and the second direction such that the aspect ratio of the partitioned light source array is matched with that of the target light field in the first direction and the second direction.

According to one embodiment of the invention, the step S203 comprises: parameters of the diffractive optical element are calculated such that the diffractive optical element splits, diverges, and light homogenization-modulates a light beam emitted from a light source in the plurality of light source arrays along the first direction, and/or the diffractive optical element splits, diverges, and light homogenization-modulates a light beam emitted from a light source in the plurality of light source arrays along the second direction.

According to one embodiment of the invention, a light field projected by each light source array after divergence and homogenization can at least reach middle of an interval between adjacent light source arrays.

According to one embodiment of the invention, the step S203 comprises: a third phase distribution of the diffractive optical element is calculated, and the third phase distribution can provide beam splitting for a light beam emitted by each light source array; the first phase distribution, the second phase distribution and the third phase distribution are superposed.

The invention also relates to an optical modulation element which is designed with the foregoing design method 200.

The forgoing describes preferred embodiments of the invention, wherein one column of partitions can be adopted, and two columns of partitions can also be adopted for a light source array of the VCSEL, which may provide different solutions, respectively. For example, a light source of the VCSEL is divided into 1*12 or 2 \*8 partitions. There are gaps (intervals) between adjacent partitions. Light source partitions are lightened in turn. When each light source partition is lightened, only a region in the target light field corresponding to the partition is illuminated uniformly. Moreover, when all partitions are lightened together, the whole target light field is illuminated uniformly, and there is no dark area caused by gaps between partitions. When one column of partitions is adopted for the light source, partitioned illumination can be realized through a single DOE. When two columns of partitions are adopted for the light source, a single DOE solution may also be used to realize uniform illumination of partitions in the target light field.

It should be noted finally that the contents described above are just preferred embodiments of the invention, and are not used to limit the invention. Although the detailed description of the invention has been provided with reference to the foregoing embodiments, those skilled in the art may still make modifications to the technical solution as recited in each of the foregoing embodiments, or conduct equivalent replacement of some technical features therein. Any modification, equivalent replacement, or improvement, if only falling into the spirit and principles as stated herein, should be included in the scope of protection of the invention.

We claim:

1. A diffractive optical element, comprising a microstructure plane, the microstructure plane provided thereon with at least one microstructural pattern unit, the diffractive optical element capable of receiving a light beam emitted from a partitioned light source array and projecting a light field on a target surface, wherein the partitioned light source array comprises a plurality of light source arrays spaced along a first direction, and the microstructural pattern unit is configured to be capable of diverging and light homogenization-modulating a light beam emitted from a light source in the plurality of light source arrays along the first direction such that light field regions projected by adjacent light source arrays on the target surface are adjoined or overlapped with each other in the first direction.

2. The diffractive optical element as claimed in claim 1, wherein the plurality of light source arrays have intervals along a second direction which is vertical to the first direction, wherein the microstructural pattern unit is configured to be capable of diverging and light homogenization-modulating a light beam emitted from a light source in the plurality of light source arrays along the second direction such that the light field regions projected by adjacent light source arrays on the target surface are adjoined or overlapped with each other in the second direction.

3. The diffractive optical element as claimed in claim 1, wherein the diffractive optical element has a focal power such that a light beam emitted by each light source array is diverged in the first direction and/or the second direction, and the microstructural pattern unit is configured to be capable of perform light homogenization modulation within a divergent scope.

4. The diffractive optical element as claimed in claim 2, wherein the diffractive optical element has different focal powers in the first direction and the second direction such that the aspect ratio of the partitioned light source array is matched with that of the light field region on the target surface in the first direction and the second direction.

5. The diffractive optical element as claimed in claim 2, wherein the microstructural pattern unit is configured to be capable of splitting, diverging and light homogenization-modulating a light beam emitted from a light source in the plurality of light source arrays along the first direction; and/or the microstructural pattern unit is configured to be capable of splitting, diverging and light homogenization-modulating a light beam emitted from a light source in the plurality of light source arrays along the second direction.

6. The diffractive optical element as claimed in claim 1, wherein the microstructural pattern unit is configured to enable a light field projected by each light source array after divergence and homogenization to reach at least middle of the interval between adjacent light source arrays.

7. A partitioned uniform light projection system, comprising:
a partitioned light source array, the partitioned light source array comprising a plurality of light source arrays spaced along a first direction, the plurality of light source arrays having intervals along the first direction;
a diffractive optical element, provided downstream of a light path of the partitioned light source array and capable of receiving a light beam emitted from the plurality of light source arrays and projecting a light field on a target surface, the diffractive optical element comprising a microstructure plane, the microstructure plane provided thereon with at least one microstructural pattern unit, the microstructural pattern unit being configured to be capable of diverging and light homogenization-modulating a light beam emitted from a light source in the plurality of light source arrays along the first direction such that light field regions projected by adjacent light source arrays on the target surface are adjoined or overlapped with each other in the first direction.

8. The partitioned uniform light projection system as claimed in claim 7, wherein the plurality of light source arrays have intervals along a second direction which is vertical to the first direction, wherein the microstructural pattern unit is configured to be capable of diverging and light homogenization-modulating a light beam emitted from a light source in the plurality of light source arrays along the second direction such that the light field regions projected by adjacent light source arrays on the target surface are adjoined or overlapped with each other in the second direction.

9. The partitioned uniform light projection system as claimed in claim 7, wherein the diffractive optical element has a focal power such that a light beam emitted by each light source array is diverged in the first direction and/or the second direction, and the microstructural pattern unit is configured to be capable of perform light homogenization modulation within a divergent scope.

10. The partitioned uniform light projection system as claimed in claim 8, wherein the diffractive optical element has different focal powers in the first direction and the second direction such that the aspect ratio of the partitioned light source array is matched with that of a light field region on the target surface in the first direction and the second direction.

11. The partitioned uniform light projection system as claimed in claim 8, wherein the microstructural pattern unit is configured to be capable of splitting, diverging and light homogenization-modulating a light beam emitted from a light source in the plurality of light source arrays along the first direction; and/or the microstructural pattern unit is configured to be capable of splitting, diverging and light homogenization-modulating a light beam emitted from a light source in the plurality of light source arrays along the second direction.

12. The partitioned uniform light projection system as claimed in claim 7, wherein the microstructural pattern unit is configured to enable a light field projected by each light source array after divergence and homogenization to reach at least middle of the interval between adjacent light source arrays.

13. A design method of a diffractive optical element, comprising:
obtaining parameters of the partitioned light source array which comprises a plurality of light source arrays, the plurality of light source arrays having intervals along a first direction, the parameters comprising widths of the intervals along the first direction;
obtaining parameters of a target light field on a target surface, comprising a distance between the target light field and the partitioned light source array;
determining parameters of the diffractive optical element such that the diffractive optical element can diverge and light homogenization-modulate a light beam emitted from a light source in the plurality of light source arrays along the first direction such that light field regions projected by adjacent light source arrays on the target surface are adjoined or overlapped with each other in the first direction.

14. The design method as claimed in claim 13, wherein the plurality of light source arrays have intervals along a second direction which is vertical to the first direction, wherein the step of determining parameters of the diffractive optical element comprise: determining the parameters of the diffractive optical element such that the diffractive optical element can diverge and light homogenization-modulate a light beam emitted from a light source in the plurality of light source arrays such that the light field regions projected by adjacent light source arrays on the target surface are adjoined or overlapped with each other in the second direction.

15. The design method as claimed in claim 13, wherein the step of determining parameters of the diffractive optical element comprise:
determining a first phase distribution of the diffractive optical element, the first phase distribution capable of providing a focal power such that a light beam emitted by each light source array is diverged in the first direction and/or the second direction;
determining a second phase distribution of the diffractive optical element, the second phase distribution capable of light homogenization-modulating a light beam emitted by each light source array within a divergent scope in the first direction and/or the second direction; and
superposing the first phase distribution and the second phase direction.

16. The design method as claimed in claim 14, wherein the step of determining parameters of the diffractive optical element comprise: determining different focal powers of the diffractive optical element in the first direction and the second direction according to the aspect ratio of the partitioned light source array in the first direction and the second direction and the aspect ratio of the target light field in the first direction and the second direction such that the aspect ratio of the partitioned light source array is matched with that of the target light field in the first direction and the second direction.

17. The design method as claimed in claim 14, wherein the step of determining parameters of the diffractive optical element comprise: determining parameters of the diffractive optical element such that the diffractive optical element splits, diverges and light homogenization-modulates a light beam emitted from a light source in the plurality of light source arrays along the first direction; and/or the diffractive optical element splits, diverges and light homogenization-modulates a light beam emitted from a light source in the plurality of light source arrays along the second direction.

18. The design method as claimed in claim 14, wherein a light field projected by each light source array after divergence and homogenization reaches at least middle of the interval between adjacent light source arrays.
